(19) United States
(12) Patent Application Publication
(10) Pub. No.: US 2025/0280496 A1
(43) Pub. Date: Sep. 4, 2025

(54) VIA ASSEMBLY FOR PRINTED CIRCUIT BOARD

(71) Applicant: Cisco Technology, Inc., San Jose, CA (US)

(72) Inventors: Mingjian Gao, Shanghai (CN); Mingtong Zuo, Shanghai (CN); Wenbin Ma, Shanghai (CN); Mike Sapozhnikov, San Jose, CA (US); Yuqing Zhu, Shanghai (CN); Shenzhi Miao, Shanghai (CN); David Nozadze, San Jose, CA (US); Brice Achkir, Livermore, CA (US)

(21) Appl. No.: 18/591,294

(22) Filed: Feb. 29, 2024

(51) Int. Cl. H05K 1/11

(52) U.S. Cl. CPC H05K 1/115; H05K 2201/10901

(57) ABSTRACT

Provided for herein is an apparatus that includes a layer of a printed circuit board, a first pair of signal vias extending through the layer, a second pair of signal vias extending through the layer, a first plurality of ground vias extending through the layer, and a second plurality of ground vias extending through the layer. Each of the pairs of signal vias are configured to propagate respective signals. The first plurality of ground vias at least partially circumferentially surround a first signal via of the first pair of signal vias, and the second plurality of ground vias at least partially circumferentially surround a second signal via of the second pair of signal vias to reduce interference of electrical fields emitted by the pairs of signal vias. The first plurality of ground vias and the second plurality of ground vias share a common ground via.

### TECHNICAL FIELD

The present disclosure relates to printed circuit boards (PCBs).

### BACKGROUND

A printed circuit board (PCB) electrically couples various electronic components with one another. For example, a PCB may include multiple layers, each having different electronic components and traces routed along the layers to electrically couple to electronic components of the same layer. Additionally, the PCB may include vias that extend between layers to electrically couple electronic components of different layers to one another. For example, a signal may propagate from a first electronic component of a first layer, through a first trace routed along the first layer, through a via extending from the first layer to a second layer, through a second trace routed along the second layer, and to an electronic component of the second layer. Unfortunately, the PCB may be subject to crosstalk in which transmitted signals interfere with one another. For example, electric fields emitted by vias during signal transmission may overlap with one another. Interference between signals may increase signal loss, thereby reducing signal integrity.

### BRIEF DESCRIPTION OF THE DRAWINGS

FIG. 1 is a side perspective cross-sectional view of a printed circuit board (PCB) that includes multiple layers, according to an example embodiment.

FIG. 2 is a side view of a PCB that includes multiple layers, according to an example embodiment.

FIG. 3 is a top perspective view of the PCB of FIG. 2.

FIG. 4 is a schematic diagram of an external layer of a PCB with ground vias surrounding pairs of signal vias, according to an example embodiment.

FIG. 5 is a schematic diagram of an internal layer of a PCB with ground vias surrounding pairs of signal vias, according to an example embodiment.

FIG. 6 is a schematic diagram of a power layer of a PCB having a ground portion with ground vias surrounding pairs of signal vias, according to an example embodiment.

FIG. 7 is a flowchart of a method for manufacturing a PCB with ground vias surrounding pairs of signal vias, according to an example embodiment.

FIG. 8 is a flowchart of a method for manufacturing a PCB that includes a power layer having a ground portion with ground vias surrounding pairs of signal vias, according to an example embodiment.

### DETAILED DESCRIPTION

### Overview

Techniques are provided herein for reducing crosstalk for a printed circuit board (PCB). In some aspects, the techniques described herein relate to an apparatus including: a layer of a printed circuit board; a first pair of signal vias extending through the layer and configured to propagate respective signals; a second pair of signal vias extending through the layer and configured to propagate respective signals; a first plurality of ground vias extending through the layer and at least partially circumferentially surrounding a first signal via of the first pair of signal vias; and a second plurality of ground vias extending through the layer and at least partially circumferentially surrounding a second signal via of the second pair of signal vias, wherein the first plurality of ground vias and the second plurality of ground vias share a common ground via.

According to other aspects, the techniques described herein relate to a method including: forming adjacent pairs of signal vias through a layer of a printed circuit board; forming a first plurality of ground vias through the layer of the printed circuit board to at least partially circumferentially surround a first signal via of a first pair of signal vias of the adjacent pairs of signal vias; and forming a second plurality of ground vias through the layer of the printed circuit board to at least partially circumferentially surround a second signal via of a second pair of signal vias of the adjacent pairs of signal vias, wherein the first plurality of ground vias and the second plurality of ground vias comprise a common ground via.

In still other aspects, the techniques described herein relate to an apparatus including: a first pair of signal vias of a printed circuit board, wherein the first pair of signal vias are configured to propagate respective signals; a second pair of signal vias of the printed circuit board, wherein the second pair of signal vias are configured to propagate respective signals, and the signal vias of the first pair of signal vias and the second pair of signal vias are offset from one another along a first axis and aligned with one another along a second axis that is perpendicular to the first axis; and a single ground via positioned between the first pair of signal vias and the second pair of signal vias along the first axis.

### Example Embodiments

Techniques discussed herein are related to a PCB having ground via arrangements to reduce crosstalk. The PCB may include adjacent pairs of signal vias configured to propagate respective signals. The PCB also may include ground vias that are arranged around each pair of signal vias to block electric field leakage between the pairs of signal vias. For example, a first plurality of ground vias may circumferentially surround a first signal via of one of the pairs of signal vias, and a second plurality of ground vias may circumferentially surround a second signal via of an adjacent pair of signal vias. The first plurality of ground vias and the second plurality of ground vias may share a common ground via positioned between the adjacent pairs of signal vias. For instance, the common ground via may be positioned equidistant to the first signal via and the second signal via.

Such an arrangement of ground vias and signal vias may enable the pairs of signal vias to be positioned more adjacent to one another while sufficiently blocking interference between electric fields. For instance, a single ground via may be positioned between the adjacent pairs of signal vias and block overlap between respective electric fields emitted by both pairs of signal vias. By positioning the pairs of signal vias more adjacent to one another, the space of the PCB may be more efficiently utilized, such as by increasing a quantity of components (e.g., a quantity of signal vias) positioned thereon.

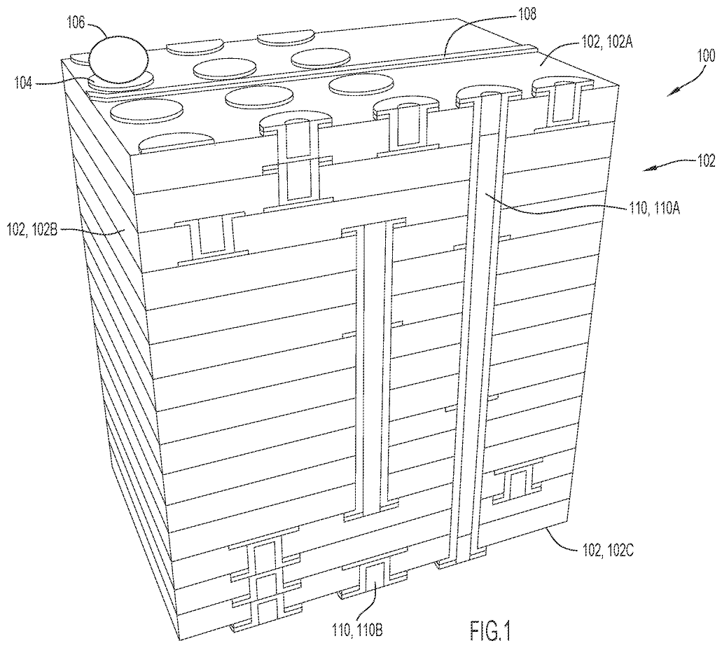

With reference made to FIG. 1, depicted therein is a cross-sectional view of a PCB 100 having multiple layers 102. Each layer 102 may include different electronic components that are electrically coupled to one another. By way of example, a first layer 102A (e.g., a top layer) may include multiple pads 104 that are exposed to an exterior environment of the PCB 100. The pads 104 may enable electrical coupling of the PCB 100 to a separate component, such as an integrated circuit (IC), such as an application-specific IC (ASIC). For example, an interconnect 106, such as a solder ball, may be used to electrically couple one of the pads 104 to the separate component. A trace 108 may also be electrically coupled to the pad 104 and routed along the first layer 102A to electrically couple the pad 104, and therefore the interconnect 106 and the separate component electrically coupled to the pad 104, to an electronic component (e.g., another IC, a resistor, a transistor, a capacitor, a switch, an inductor, a transformer, a sensor, a diode, a relay) of the first layer 102A.

Moreover, the PCB 100 may include signal vias 110 that extend through multiple layers 102 of the PCB 100 to electrically couple electronic components of different layers 102 to one another. For instance, a first signal via 110A may be electrically coupled to the pad 104 that is electrically coupled to the interconnect 106, and the first signal via 110A may extend from the first layer 102A to a second layer 102B (e.g., an inner layer, a mid layer) of the PCB 100. A trace routed along the second layer 102B may be electrically coupled to the first signal via 110A and to an electronic component of the second layer 102B. As such, the first signal via 110A may help electrically couple the electronic component of the second layer 102B to the electronic component of the first layer 102A and/or to the separate component electrically coupled to the pad 104.

By way of example, during operation of the PCB 100, a signal may be transmitted between the electronic component of the first layer 102A, the electronic component of the second layer 102B, and/or the separate component electrically coupled to the PCB 100. For instance, the separate component may transmit the signal to the pad 104 by way of the interconnect 106, and the signal may propagate through the trace 108 secured/connected to the pad 104 and routed along the first layer 102A toward the electronic component of the first layer 102A and/or through the first signal via 110A toward the second layer 102B, through the trace routed along the second layer 102B and electrically coupled to the first signal via 110A, and toward the electronic component of the second layer 102B.

However, an integrity of the signal propagated through the first signal via 110A may be reduced as a result of electrical field interferences. For example, the first signal via 110A may extend from the first layer 102A to a third layer 102C (e.g., a bottom layer) and may transmit a signal from the first layer 102A toward the third layer 102C. A second signal via 110B may extend from the third layer 102C and terminate prior to the first layer 102A and may transmit a signal from the third layer 102C toward the first layer 102A. Signal transmission along the first signal via 110A toward the third layer 102C may cause an electrical field to be emitted from the first signal via 110A toward the second signal via 110B, and signal transmission along the second signal via 110B from the third layer 102C toward the first layer 102A may cause an electrical field to be emitted from the second signal via 110B toward the first signal via 110A. Consequently, the electrical field emitted by the second signal via 110B may overlap with the electrical field emitted by the first signal via 110A to reduce an integrity of the respective signals propagated along the first signal via 110A and along the second signal via 110B. The reduced integrity of the signals may reduce operation of the PCB 100.

For this reason, the PCB 100 may include components to reduce electrical field interference between the signal vias 110 to maintain desirable integrity of signals. As an example, respective ground vias may surround the signal vias 110, and the respective ground vias may share a common ground via positioned between the vias 110. Such an arrangement of the ground vias may block the electrical fields from interfering with one another, thereby improving signal integrity and operation of the PCB 100.

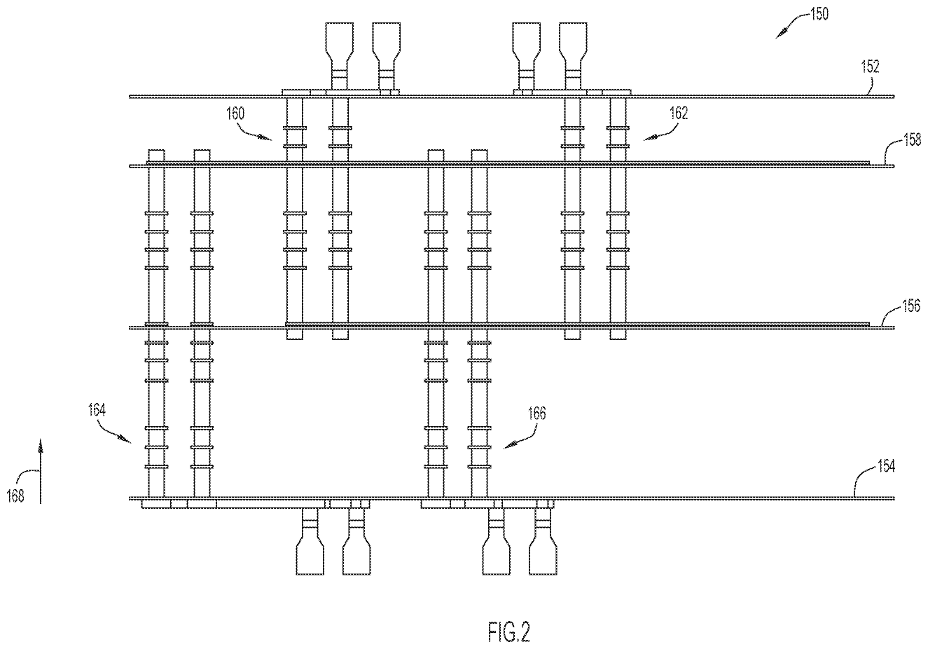

FIG. 2 is a schematic diagram of a PCB 150. The PCB 150 may include a first layer 152 (e.g., a top layer), a second layer 154 (e.g., a bottom layer), a third layer 156 (e.g., a first inner layer), and a fourth layer 158 (e.g., a second inner layer). Other layers of the PCB 150, such as ground layers between the depicted layers 152, 154, 156, 158, are not illustrated for visualization purposes. The PCB 150 may also include a first pair of signal vias 160, a second pair of signal vias 162, a third pair of signal vias 164, and a fourth pair of signal vias 166. Each of the first pair of signal vias 160 and the second pair of signal vias 162 may extend from the first layer 152 to the third layer 156, and each of the third pair of signal vias 164 and the fourth pair of signal vias 166 may extend from the second layer 154 to the fourth layer 158. By way of example, the first pair of signal vias 160 and the second pair of signal vias 162 may each transmit respective signals from the first layer 152 toward the third layer 156, and the third pair of signal vias 164 and the fourth pair of signal vias 166 may transmit respective signals from the second layer 154 toward the fourth layer 158. The respective signals transmitted by each pair of signal vias 160, 162, 164, 166 may include a positive signal and a negative signal in some embodiments.

The first pair of signal vias 160 and the second pair of signal vias 162 may overlap with the third pair of signal vias 164 and/or the fourth pair of signal vias 166 along an axis 168 (e.g., a vertical axis, a Z-axis). For instance, the fourth layer 158 at which the third pair of signal vias 164 and the fourth pair of signal vias 166 terminate may be adjacent to the first layer 152 (e.g., separated by relatively fewer ground layers) from which the first pair of signal vias 160 and the second pair of signal vias 162 extend, whereas the third layer 156 at which the first pair of signal vias 160 and the second pair of signal vias 162 terminate may be adjacent to the second layer 154 (e.g., separated by relatively fewer ground layers) from which the third pair of signal vias 164 and the fourth pair of signal vias 166 extend. Consequently, signals propagated along the first pair of signal vias 160 and/or along the second pair of signal vias 162 from the first layer 152 toward the third layer 156 may cause electrical fields to be emitted from the first pair of signal vias 160 and/or from the second pair of signal vias 162 toward the third pair of signal vias 164 and/or toward the fourth pair of signal vias 166. Additionally or alternatively, signals propagated along the third pair of signal vias 164 and/or along the fourth pair of signal vias 166 from the second layer 154 toward the fourth layer 158 may cause electrical fields to be emitted from the third pair of signal vias 164 and/or from the fourth pair of signal vias 166 toward the first pair of signal vias 160 and/or toward the second pair of signal vias 162. However, the PCB 100 may include ground vias (not shown) positioned to block such electrical fields from interfering with one another. By way of example, the ground vias may extend through any of the layers 152, 154, 156, 158 to contain and isolate the electrical fields. As such, even though the first pair of signal vias 160 and the second pair of signal vias 162 may overlap with the third pair of signal vias 164 and the fourth pair of signal vias 166 along the axis 168 to cause electrical fields to be emitted from one of the pairs of signal vias 160, 162, 164, 166 toward another (e.g., an adjacent) pair of the signal vias 160, 162, 164, 166, overlap between the electrical fields may be limited to maintain desirable integrity of the signals propagated along the pairs of signal vias 160, 162, 164, 166.

The overlap of adjacent pairs of signal vias 160, 162, 164, 166 along the axis 168 may enable more efficient usage of the PCB 150 to propagate signals. As an example, adjacent pairs of signal vias 160, 162, 164, 166 that overlap along the axis 168 may be positioned more proximate to one another while achieving desirable signal integrity. As another example, layers of the PCB 150 may be used more readily. For instance, instead of limiting extension of the pairs of signal vias 160, 162, 164, 166 through the layers 152, 154, 156, 158 to avoid overlap with one another along the axis 168 (e.g., by terminating the third pair of signal vias 164 and/or the fourth pair of signal vias 166 prior to the fourth layer 158 and/or by terminating the first pair of signal vias 160 and/or the second pair of signal vias 162 prior to the third layer 156), each pair of signal via 160, 162, 164, 166 may extend to and terminate at any of the layers 152, 154, 156, 158, such as to overlap with one another along the axis 168, without compromising signal integrity. Additionally or alternatively, the PCB 150 may include fewer layers that otherwise may be used to offset the pairs of signal vias 160, 162, 164, 166 along the axis 168. In either case, the PCB 150 may be more efficiently utilized, such as by increasing a quantity of components that can be arranged on the PCB 150 and/or by reducing an amount of material used to manufacture the PCB 150 (e.g., an excessive quantity of layers of the PCB 150). As a result, operation of the PCB 150 may be improved and/or a cost of manufacture of the PCB 150 may be reduced.

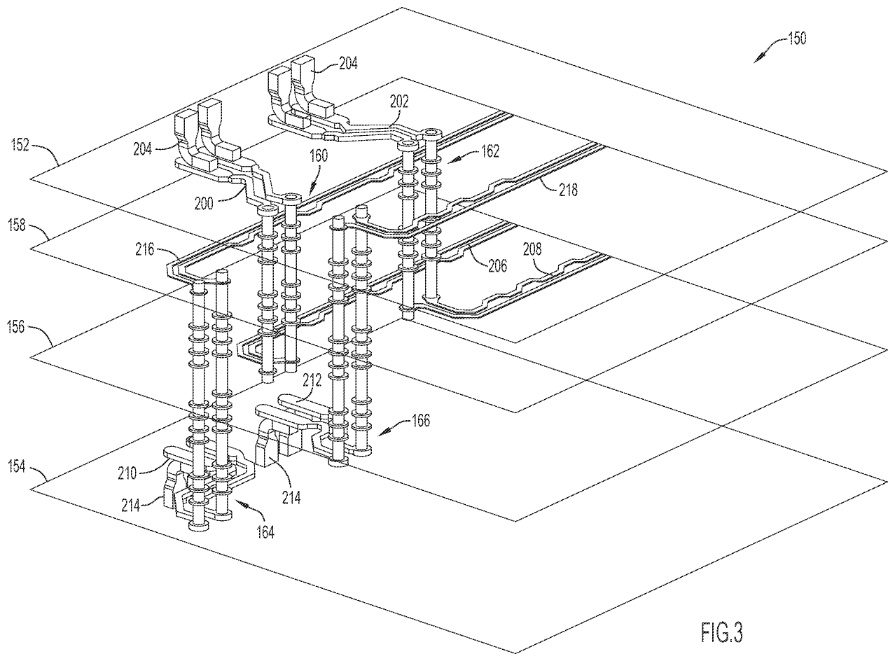

FIG. 3 is a top perspective view of the PCB 150 that includes the first pair of signal vias 160 and the second pair of signal vias 162 extending from the first layer 152 to the third layer 156 and the third pair of signal vias 164 and the fourth pair of signal vias 166 extending from the second layer 154 to the fourth layer 158. The PCB 150 may also include first traces 200 routed along the first layer 152 and coupled to the first pair of signal vias 160, as well as second traces 202 routed along the first layer 152 and coupled to the second pair of signal vias 162. For example, the first traces 200 and the second traces 202 may propagate signals between the PCB 150 and a separate electrical component (e.g., an IC) at the first layer 152. To this end, first interconnects 204 may be coupled to each of the first traces 200 and second traces 202 for coupling to the separate electrical component. Furthermore, third traces 206 may be routed along the third layer 156 and coupled to the first pair of signal vias 160, and fourth traces 208 may be routed along the third layer 156 and coupled to the second pair of signal vias 162, such as for connection with an electrical component at the third layer 156. Thus, signals may be transmitted between the separate electrical component at the first layer 152 and the electrical component at the third layer 156 by way of the first interconnects 204, the first traces 200, the first pair of signal vias 160, and the third traces 206 and/or by way of the first interconnects 204, the second traces 202, the second pair of signal vias 162, and the fourth traces 208.

The PCB 150 may further include fifth traces 210 routed along the second layer 154 and coupled to the third pair of signal vias 164, as well as sixth traces 212 routed along the second layer 154 and coupled to the fourth pair of signal vias 166. For instance, the fifth traces 210 and the sixth traces 212 may propagate signal between the PCB 150 and another separate component (e.g., another IC) at the second layer 154 using second interconnects 214 coupled to each of the fifth traces 210 and sixth traces 212. As such, the PCB 150 may have a belly-to-belly configuration in which the first layer 152 and the second layer 154 at opposite sides of the PCB 150 are connected to a respective, separate electrical component. Moreover, seventh traces 216 may be routed along the fourth layer 158 and coupled to the third pair of signal vias 164, and eighth traces 218 may be routed along the fourth layer 158 and coupled to the fourth pair of signal vias 166, such as for connection with an electrical component at the fourth layer 158. As such, signals may be transmitted between the separate electrical component at the second layer 154 and the electrical component at the fourth layer 158 by way of the second interconnects 214, the fifth traces 210, the third pair of signal vias 164, and the seventh traces 216 and/or by way of the second interconnects 214, the sixth traces 212, the fourth pair of signal vias 166, and the eighth trace 218.

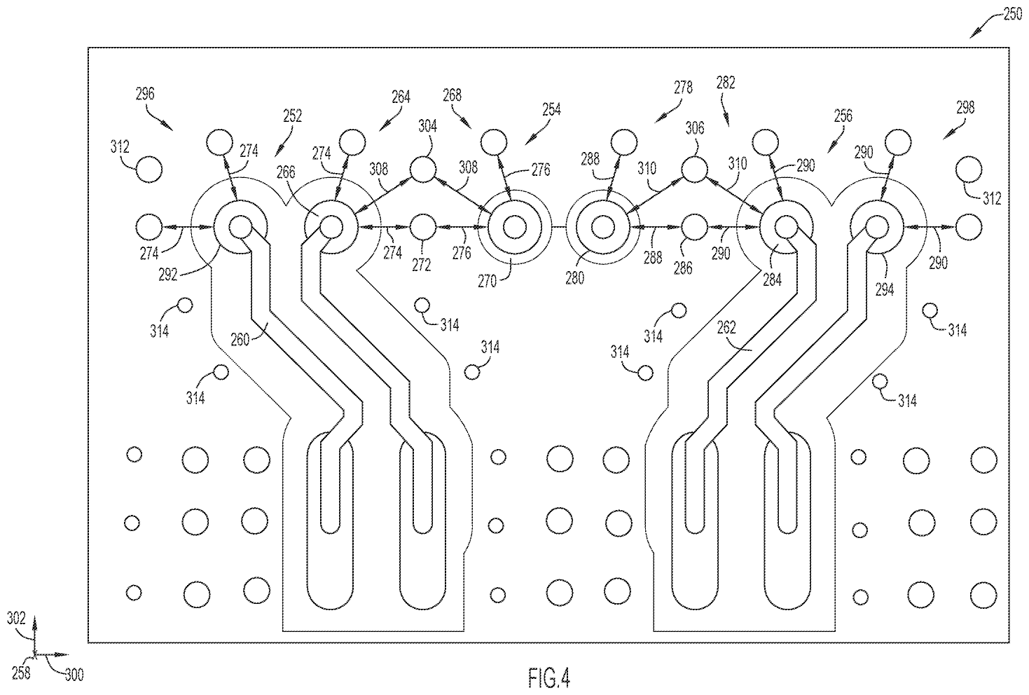

FIG. 4 is a schematic diagram of a layer 250 (e.g., an external layer) of the PCB 150, such as of the first layer 152 and/or of the second layer 154. A first pair of signal vias 252, a second pair of signal vias 254, and a third pair of signal vias 256 may be formed at the layer 250. For instance, each pair of signal vias 252, 254, 256 may extend through the layer 250 along a first axis 258 in overlap with one another. First traces 260 may be coupled to the first pair of signal vias 252 and routed along the layer 250, and second traces 262 may be coupled to the third pair of signal vias 256 and routed along the layer 250, such as to couple the first pair of signal vias 252 and the third pair of signal vias 256 to other electrical components at the layer 250. However, no traces routed along the layer 250 may be coupled to the second pair of signal vias 254. Thus, the second pair of signal vias 254 may not be coupled to another electrical component at the layer 250.

Signal propagation along the pairs of signal vias 252, 254, 256 may cause electrical fields to be emitted. To block interference between the electrical fields, ground vias may be arranged to isolate the electrical fields. By way of example, a first plurality of ground vias 264 may at least partially circumferentially surround a first signal via 266 of the first pair of signal vias 252, a second plurality of ground vias 268 may at least partially circumferentially surround a second signal via 270 of the second pair of signal vias 254, and the first plurality of ground vias 264 and the second plurality of ground vias 268 may share a first common ground via 272 positioned between the first signal via 266 and the second signal via 270. That is, the first signal via 266 may be positioned at the same first distance 274 away from each of the first plurality of ground vias 264, including the first common ground via 272, and the second signal via 270 may be positioned at the same second distance 276 away from each of the second plurality of ground vias 268, including the first common ground via 272. For instance, the first distance 274 and the second distance 276 may be approximately equal to one another. Such an arrangement of the first plurality of ground vias 264 about the first signal via 266 and of the second plurality of ground vias 268 about the second signal via 270 may block electrical fields emitted by the first signal via 266 and electrical fields emitted by the second signal via 270 from interfering with one another. That is, the first plurality of ground vias 264 may isolate the electrical fields emitted by the first signal via 266, and the second plurality of ground vias 268 may isolate the electrical fields emitted by the second signal via 270. The first common ground via 272 may help isolate the electrical fields emitted by both the first signal via 266 and the second signal via 270. As such, the first plurality of ground vias 264 and the second plurality of ground vias 268 may efficiently isolate the electrical fields to maintain desirable signal integrity (e.g., by using a limited quantity of ground vias and/or by enabling the first signal via 266 and the second signal via 270 to be positioned more adjacent to one another).

A third plurality of ground vias 278 may at least partially circumferentially surround a third signal via 280 of the second pair of signal vias 254, a fourth plurality of ground vias 282 may at least partially circumferentially surround a fourth signal via 284 of the third pair of signal vias 256, and the third plurality of ground vias 278 and the fourth plurality of ground vias 282 may share a second common ground via 286 positioned between the third signal via 280 and the fourth signal via 284. As such, the third signal via 280 may be positioned at the same third distance 288 away from each of the third plurality of ground vias 278, including the second common ground via 286, and the fourth signal via 284 may be positioned at the same fourth distance 290 away from each of the fourth plurality of ground vias 282, including the second common ground via 286. For example, the third distance 288 and the fourth distance 290 may be approximately equal to one another. Thus, the third plurality of ground vias 278 and the fourth plurality of ground vias 282 may block electrical fields emitted by the third signal via 280 and electrical fields emitted by the fourth signal via 284 from interfering with one another to efficiently isolate the electrical fields and maintain desirable signal integrity. In some embodiments, the second distance 276 and the third distance 288 are approximately equal to one another such that the second plurality of ground vias 268 and the third plurality of ground vias 278 are symmetrical to one another about the second pair of signal vias 254.

Ground vias may also be similarly positioned about a fifth signal via 292 of the first pair of signal vias 252 and/or about a sixth signal via 294 of the third pair of signal vias 256. That is, a fifth plurality of ground vias 296 may at least partially circumferentially surround the fifth signal via 292 and/or a sixth plurality of ground vias 298 may at least partially circumferentially surround the sixth signal via 294. For example, the fifth signal via 292 may be positioned at the first distance 274 away from each of the fifth plurality of ground vias 296, and/or the sixth signal via 294 may be positioned at the fourth distance 290 away from each of the sixth plurality of ground vias 298. Therefore, the first plurality of ground vias 264 and the fifth plurality of ground vias 296 may be symmetrical to one another about the first pair of signal vias 252 and/or the fourth plurality of ground vias 282 and the sixth plurality of ground vias 298 may be symmetrical to one another about the third pair of signal vias 256.

In certain embodiments, each signal via 266, 270, 280, 284, 292, 294 may be offset from one another along a second axis 300 (e.g., a first horizontal axis), perpendicular to the first axis 258, and aligned with one another along a third axis 302 (e.g., a second horizontal axis), perpendicular to the first axis 258 and to the second axis 300. The first common ground via 272 and the second common ground via 286 may also be offset from the signal vias 266, 270, 280, 284, 292, 294 along the second axis 300 and aligned with the signal vias 266, 270, 280, 284, 292, 294 along the third axis 302. Thus, the pairs of signal vias 252, 254, 256 and the common ground vias 272, 286 may be collinear with one another. Moreover, a first intermediate ground via 304 may be positioned between the first signal via 266 and the second signal via 270 along the second axis 300 and further help isolate electrical fields emitted by both the first signal via 266 and by the second signal via 270. For instance, the first intermediate ground via 304 may be aligned with the first common ground via 272 along the second axis 300 and offset from the first common ground via 272 along the third axis 302. The first intermediate ground via 304 may be positioned at a fifth distance 308, greater than the first distance 274 and the second distance 276, away from the first signal via 266 and away from the second signal via 270. Therefore, the first plurality of ground vias 264, the second plurality of ground vias 268, and the first intermediate ground via 304 may cooperatively form a Y-shaped arrangement. A second intermediate ground via 306 may be positioned between the third signal via 280 and the fourth signal via 284 along the second axis 300 and further help isolate electrical fields emitted by both the third signal via 280 and by the fourth signal via 284. The second intermediate ground via 306 may be aligned with the second common ground via 286 along the second axis 300 and offset from the second common ground via 286 along the third axis 302. The second intermediate ground via 306 may be positioned at a sixth distance 310 (e.g., the same as the fifth distance 308), greater than the third distance 288 and the fourth distance 290, away from the third signal via 280 and away from the fourth signal via 284. In this manner, the third plurality of ground vias 278, the fourth plurality of ground vias 282, and the second intermediate ground via 306 may cooperatively form a Y-shaped arrangement. Further still, additional, respective vias 312 may be positioned to isolate electric fields emitted by the fifth signal via 292 and by the sixth signal via 294.

The first plurality of ground vias 264 and the fifth plurality of ground vias 296 may provide sufficient space for the first traces 260 to be routed from the first pair of signal vias 252 in directions away from the first plurality of ground vias 264 and from the fifth plurality ground vias 296. In addition, the fourth plurality of ground vias 282 and the sixth plurality of ground vias 298 may provide sufficient space for the second traces 262 to be routed from the third pair of signal vias 256 in directions away from the fourth plurality of ground vias 282 and from the sixth plurality of ground vias 298. Respective ground microvias 314 may surround the traces 260, 262 to block interference of electrical fields emitted as a result of signal propagation along the traces 260, 262. Thus, the ground microvias 314 may further help maintain signal integrity. Although the traces 260, 262 may transmit signals along the layer 250 in the illustrated embodiment, another component, such as a microstrip and/or an interconnect, may be used for transmitting signals along the layer 250 in additional or alternative embodiments.

Additionally, in the illustrated embodiment, no ground vias are positioned between the first plurality of ground vias 264 and the fifth plurality of ground vias 296 along the second axis 300, between the second plurality of ground vias 268 and the third plurality of ground vias 278 along the second axis 300, and between the fourth plurality of ground vias 282 and the sixth plurality of ground vias 298 along the second axis 300. Accordingly, six respective ground vias surround each pair of signal vias 252, 254, 256 to sufficiently isolate electrical fields emitted by the pairs of signal vias 252, 254, 256.

In some embodiments, each of the ground vias 264, 268, 278, 282, 296, 298, 304, 306, 312 may extend through multiple layers of the PCB 150. For example, each of the signal vias 266, 270, 280, 284, 292, 294 may extend through another layer of the PCB 150 in addition to the layer 250, and the ground vias 264, 268, 278, 282, 296, 298, 304, 306, 312 may extend through corresponding layers to isolate electrical fields emitted by the signal vias 266, 270, 280, 284, 292, 294 at each layer. However, the traces 260, 262 may be routed along the layer 250 and not along another layer of the PCB 150. Therefore, the ground microvias 314 may extend through the layer 250 and not through another layer of the PCB 150 to sufficiently isolate electrical fields emitted by the traces 260, 262.

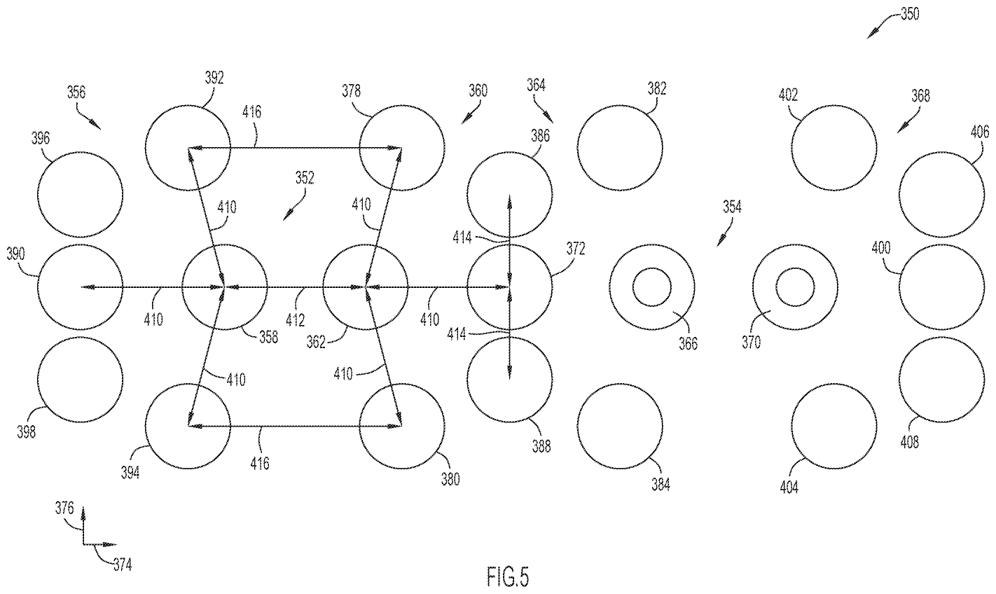

FIG. 5 is a schematic diagram of a layer 350 (e.g., an internal layer) of the PCB 150, such as of the third layer 156 and/or of the fourth layer 158. A first pair of signal vias 352 and a second pair of signal vias 354 may be formed at the layer 350. A first plurality of ground vias 356 may at least partially circumferentially surround a first signal via 358 of the first pair of signal vias 352, a second plurality of ground vias 360 may at least partially circumferentially surround a second signal via 362 of the first pair of signal vias 352, a third plurality of ground vias 364 may at least partially circumferentially surround a third signal via 366 of the second pair of signal vias 354, and a fourth plurality of ground vias 368 may at least partially circumferentially surround a fourth signal via 370 of the second pair of signal vias 354. In the FIG. 5, no traces are illustrated. However, in some embodiments, traces may be coupled to the first pair of signal vias 352 and/or the second pair of signal vias 354. For example, the traces routed along the layer 350 may be relatively narrower as compared to the traces 260, 262 routed along the layer 250. As such, the traces may be accommodated by and routed through a smaller space. For this reason, a greater quantity of ground vias 356, 360, 364, 368 may more fully surround each signal via 358, 362, 366, 370, respectively, as compared to the respective ground vias surrounding the signal vias 266, 284, 292, 294 to which traces 260, 262 are coupled at the layer 250, while providing a sufficient amount of space to enable traces to be routed between the ground vias 356, 360, 364, 368. For instance, ten respective ground vias may surround each pair of signal vias 352, 354.

By way of example, the second plurality of ground vias 360 and the third plurality of ground vias 364 may share a common ground via 372. In some embodiments, the signal vias 358, 362, 366, 370 and the common ground via 372 may be offset from one another along a first axis 374 (e.g., a first horizontal axis) and aligned with one another along a second axis 376 (e.g., a second horizontal axis). The second plurality of ground vias 360 may also include a first ground via 378 and a second ground via 380. The first ground via 378 and the second ground via 380 may be aligned with one another along the first axis 374 and offset from one another along the second axis 376. The third plurality of ground vias 364 may include a third ground via 382 and a fourth ground via 384 that are aligned with one another along the first axis 374 and offset from one another along the second axis 376. As an example, the third ground via 382 may be aligned with the first ground via 378 along the second axis 376, and the fourth ground via 384 may be aligned with the second ground via 380 along the second axis 376. A first intermediate ground via 386 may be positioned adjacent to the first ground via 378 and to the third ground via 382, offset from the common ground via 372 along the second axis 376, and aligned with the common ground via 372 along the first axis 374. A second intermediate ground via 388 may be positioned adjacent to the second ground via 380 and to the fourth ground via 384, offset from the common ground via 372 along the second axis 376, and aligned with the common ground via 372 along the first axis 374. As such, the second plurality of ground vias 360, the third plurality of ground vias 364, the first intermediate ground via 386, and the second intermediate ground via 388 may cooperatively isolate electrical fields emitted from the second signal via 362 and from the third signal via 366.

The first plurality of ground vias 356 may include a fifth ground via 390 aligned with the first signal via 358 along the second axis 376 and offset from the first signal via 358 along the first axis 374, as well as a sixth ground via 392 and a seventh ground via 394 aligned with one another along the first axis 374 and offset from one another along the second axis 376. For example, the sixth ground via 392 may be aligned with the first ground via 378 along the second axis 376, and the seventh ground via 394 may be aligned with the second ground via 380 along the second axis 376. A third intermediate ground via 396 positioned adjacent to the sixth ground via 392 and a fourth intermediate ground via 398 positioned adjacent to the seventh ground via 394 may be aligned with one another along the first axis 374 and offset from one another along the second axis 376. For instance, the third intermediate ground via 396 may be aligned with the first intermediate ground via 386 along the second axis 376, and the fourth intermediate ground via 398 may be aligned with the second intermediate ground via 388 along the second axis 376. In this manner, the first plurality of ground vias 356, the second plurality of ground vias 360, and the intermediate ground vias 386, 388, 396, 398 may be symmetrical to one another about the first pair of signal vias 352.

Similarly, the fourth plurality of ground vias 368 may include an eighth ground via 400 aligned with the fourth signal via 370 along the second axis 376 and offset from the fourth signal via 370 along the first axis 374, as well as a ninth ground via 402 and a tenth ground via 404 aligned with one another along the first axis 374 and offset from one another along the second axis 376. The ninth ground via 402 may be aligned with the third ground via 382 along the second axis 376, and the tenth ground via 404 may be aligned with the fourth ground via 384 along the second axis 376. A fifth intermediate ground via 406 positioned adjacent to the ninth ground via 402 and a sixth intermediate ground via 408 positioned adjacent to the tenth ground via 404 may be aligned with one another along the first axis 374 and offset from one another along the second axis 376. As an example, the fifth intermediate ground via 406 may be aligned with the first intermediate ground via 386 along the second axis 376, and the sixth intermediate ground via 408 may be aligned with the second intermediate ground via 388 along the second axis 376. As such, the third plurality of ground vias 364, the fourth plurality of ground vias 368, and the intermediate ground vias 386, 388, 406, 408 may be symmetrical to one another about the second pair of signal vias 354. Indeed, the ground vias 378, 380, 390, 392, 394, 396, 398 cooperatively surrounding the first pair of signal vias 352 and the ground vias 382, 384, 400, 402, 404, 406, 408 cooperatively surrounding the second pair of signal vias 354 may be symmetrical to one another about the ground vias 372, 386, 388 positioned between the pairs of signal vias 352, 354.

In some embodiments, the respective center of each of the first plurality of ground vias 356 may be at a first distance 410 away from the center of the first signal via 358, and the respective center of each of the second plurality of ground vias 360 may also be at the first distance 410 away from the center of the second signal via 362. Similarly, the respective center of each of the third plurality of ground vias 364 may be at the first distance 410 away from the center of the third signal via 366, and the respective center of each of the fourth plurality of ground vias 368 may be at the first distance 410 away from the center of the fourth signal via 370. By way of example, the first distance 410 may be a value between 0.5 millimeters (mm) and 0.7 mm (i.e., between 0.02 inches (in) and 0.028 in). Additionally, the center of the first signal via 358 may be at a second distance 412 away from the center of the second signal via 362. Similarly, the center of the third signal via 366 may be at the second distance 412 away from the center of the fourth signal via 370. For example, the second distance 412 may be substantially similar to the first distance 410. The respective centers of the first intermediate via 386 and of the second intermediate via 388 may be at a third distance 414 away from the center of the common ground via 372. The third distance 414 may be substantially less than the first distance 410 and the second distance 412. For instance, the third distance 414 may be a value between 0.35 mm and 0.4 mm (i.e., between 0.014 in and 0.016 in). The respective centers of the third intermediate via 396 and of the fourth intermediate via 398 may also be at the third distance 414 away from the center of the fifth ground via 390, and/or the respective centers of the fifth intermediate ground via 406 and of the sixth intermediate ground via 408 may be at the third distance 414 away from the center of the eighth ground via 400. Further still, the center of the first ground via 378 may be at a fourth distance 416 away from the center of the sixth ground via 392, the center of the second ground via 380 may be at the fourth distance 416 away from the center of the seventh ground via 394, the center of the third ground via 382 may be at the fourth distance 416 away from the center of the ninth ground via 402, and/or the center of the fourth ground via 384 may be at the fourth distance 416 away from the center of the tenth ground via 404. The fourth distance 416 may be substantially greater than each of the first distance 410, the second distance 412, and the third distance 414. As an example, the fourth distance 416 may be a value between 0.84 mm and 0.91 mm (i.e., between 0.033 in and 0.036 in).

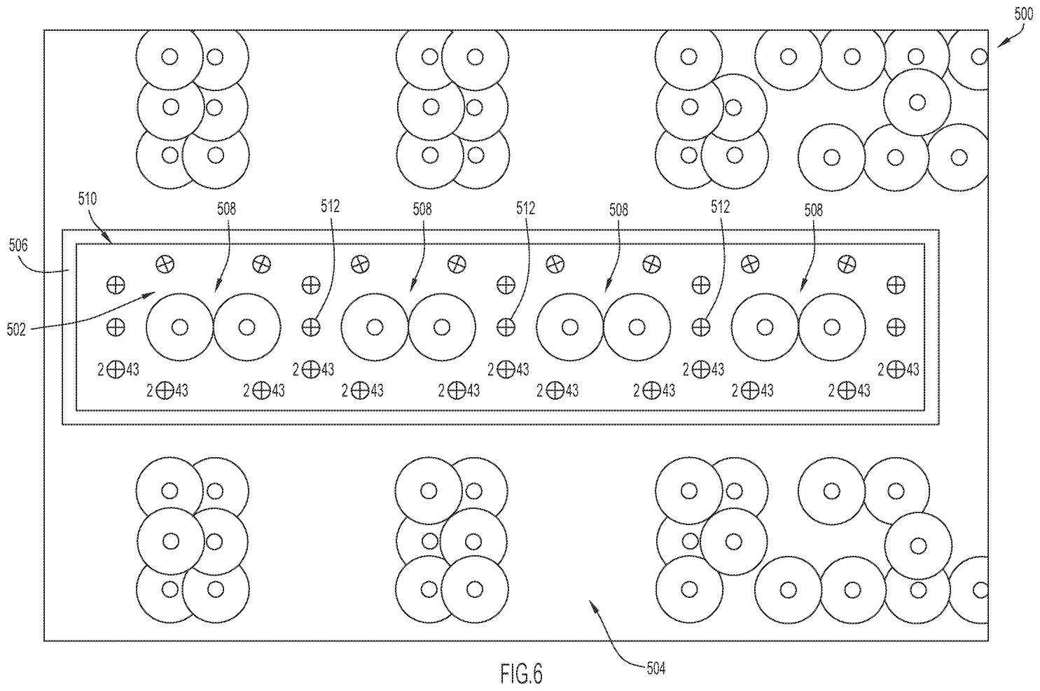

FIG. 6 is a schematic diagram of a layer 500 of the PCB 150, such as of the first layer 152, of the second layer 154, of the third layer 156, and/or of the fourth layer 158. The layer 500 may be a power layer configured to receive and direct power to electrical components at the layer 500. However, the layer 500 may also include a ground portion 502 that does not receive and direct power. For example, the layer 500 may include a power section 504 (e.g., a power shape, a power plane) with a cutout or opening 506, and the ground portion 502 (e.g., a ground shape, a ground plane) may be positioned within the cutout 506 to avoid contact with the power section 504. The ground portion 502 may therefore be isolated from the power directed by the power section 504. As such, the ground portion 502 may also avoid redirecting power away from the power section 504, thereby enabling power to be more efficiently utilized at the layer 500 by the power section 504, such as by providing a sufficient current path along the power section 504 for power to travel.

Additionally, pairs of signal vias 508 may extend through the layer 500 at the ground portion 502 such that the ground portion 502 blocks power from being directed to the signal vias 508 at the layer 500. Ground vias 510 may be positioned about the pairs of signal vias 508 in a similar arrangement as that described with respect to FIG. 5. That is, respective ground vias 510 may at least partially circumferentially surround each of the signal vias 508, and a respective common ground via 512 (e.g., a single common ground via 512) may be positioned between adjacent pairs of signal vias 508.

The ground portion 502 may help maintain desirable integrity of signals propagated along the signal vias 508 at the layer 500. For example, the ground portion 502 may limit resonance that otherwise may reduce signal integrity and that otherwise may be present without the ground portion 502 (e.g., to isolate the signal vias 508 from the power section 504 by a large void provided with the cutout 506). However, in additional or alternative embodiments, the layer 500 may not include the ground portion 502, and the signal vias 508 and the ground vias 510 may therefore extend through the space provided by the cutout 506 to avoid receiving power.

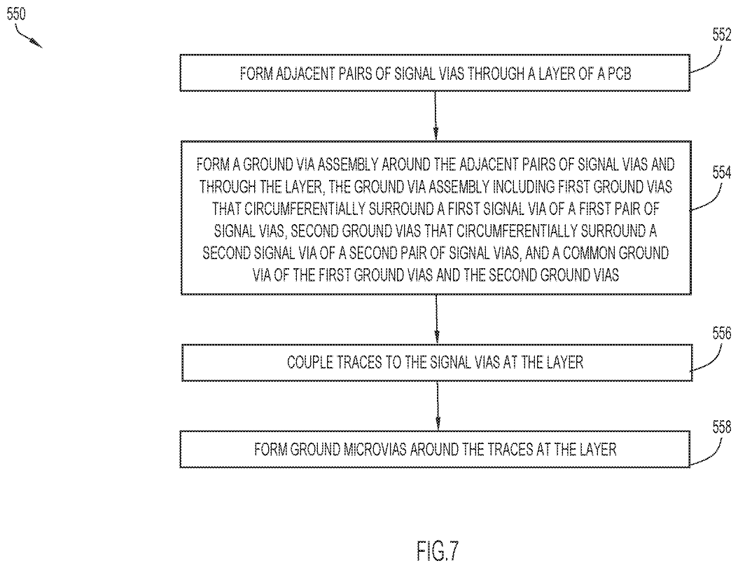

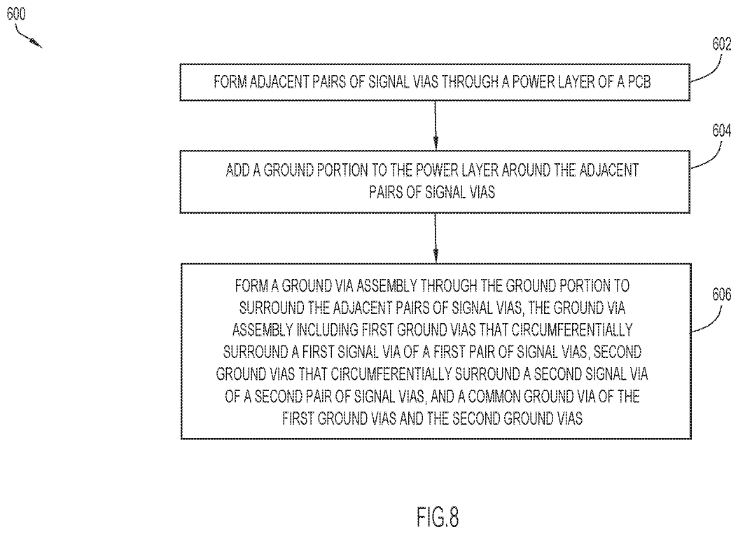

Each of FIGS. 7 and 8 discussed below illustrates a respective method for manufacturing a PCB, such as any of the PCBs 100, 150 discussed herein. In certain embodiments, the methods may be performed differently than depicted. For example, an additional operation may be performed, any of the operations may be performed differently than depicted, any of the operations may not be performed, and/or the operations may be performed in a different order. Furthermore, the respective operations of the methods may be performed in any manner relative to one another, such as sequentially and/or concurrently.

FIG. 7 is a flowchart of a method 550 for manufacturing a PCB. At step 552, adjacent pairs of signal vias may be formed through a layer of the PCB. The signal vias of the pairs of signal vias may be aligned with one another along a first horizontal axis and offset from one another along a second horizontal axis, perpendicular to the first horizontal axis. The signal vias may be configured to propagate respective signals. For example, each pair of signal vias may be a differential pair in which one of the signal vias transmits a positive signal and the other of the signal vias transmits a corresponding negative signal.

At step 554, a ground via assembly is formed around the adjacent pairs of signal vias through the layer of the PCB. The ground via assembly may include a first plurality of ground vias that at least partially circumferentially surrounds a first signal via of a first pair of signal vias and a second plurality of ground vias that at least partially circumferentially surrounds a second signal via of a second pair of signal vias. The first plurality of ground vias may isolate electrical fields emitted by the first signal via (e.g., toward the second signal via), and the second plurality of ground vias may isolate electrical fields emitted by the second signal via (e.g., toward the first signal via). Thus, the first plurality of ground vias and the second plurality of ground vias may cooperatively block respective electrical fields emitted by the first signal via and by the second signal via from interfering with one another, thereby helping maintain integrity of respective signals transmitted by the first signal via and by the second signal via.

Additionally, the first plurality of ground vias and the second plurality of ground vias may share a common ground via positioned between the first signal via and the second signal via. For instance, the common ground via may be aligned with the first signal via and with the second signal via along the first horizontal axis and offset from the first signal via and from the second signal via along the second horizontal axis. In other words, the pairs of signal vias may be offset from one another along the second horizontal axis by a single ground via (i.e., the common ground via). The common ground via may help isolate each of the respective electrical fields emitted by the first signal via and by the second signal via. As a result, the ground via assembly may enable the pairs of signal vias to be positioned more adjacent to one another without reducing signal integrity.

At step 556, traces may be coupled to any of the pairs of signal vias at the layer of the PCB. To this end, the ground via assembly (e.g., the first plurality of ground vias, the second plurality of ground vias) may be positioned to provide a sufficient amount of space to enable routing of the traces from the signal vias along the layer. By way of example, traces coupled to the first pair of signal vias may extend away from the first plurality of ground vias, and traces coupled to the second pair of signal vias may extend away from the second plurality of ground vias. The traces may enable signal transmission from the signal vias along the layer of the PCB, such as to another electrical component at the layer.

At step 558, ground microvias may be formed around the traces at the layer. The ground microvias may block electrical fields emitted from the traces as a result of signal propagation along the traces. Thus, the ground microvias may further help maintain desirable signal integrity. In some embodiments, the ground vias of the ground via assembly may extend through each layer through which the pairs of signal vias extend to isolate electrical fields emitted by the signal vias at each layer. However, the ground microvias may extend through the layer and not through other layers of the PCB to isolate electrical fields emitted by the traces, which may be routed along the layer and not along other layers of the PCB.

FIG. 8 is a flowchart of an embodiment of a method 600 for manufacturing a PCB. At step 602, adjacent pairs of signal vias may be formed through a power layer of the PCB. For instance, the power layer may include a power portion (e.g., a power shape, a power plane) configured to direct power therethrough. The power portion may include a cutout or opening, and the pairs of signal vias may be positioned in the cutout to avoid contact with the power portion. As such, the pairs of signal vias may avoid receiving power directed through the power portion.

At step 604, a ground portion (e.g., a ground shape, a ground plane) may be added to the power layer around the adjacent pairs of signal vias, such as by positioning the ground portion within the cutout of the power portion. The ground portion may isolate the pairs of signal vias from the power portion while reducing or limiting resonance that otherwise may be caused by an abundance of space surrounding the signal vias (e.g., as provided by the cutout). Thus, the ground portion may help improve signal integrity.

At step 606, a ground via assembly is formed through the ground portion to surround the adjacent pairs of signal vias. The ground via assembly may include a first plurality of ground vias that at least partially circumferentially surrounds a first signal via of a first pair of signal vias and a second plurality of ground vias that at least partially circumferentially surrounds a second signal via of a second pair of signal vias to isolate respective electrical fields emitted by the first signal via and by the second signal via. The first plurality of ground vias and the second plurality of ground vias may share a common ground via that may help isolate each respective electrical field emitted by the first signal via and by the second signal via. Thus, the ground via assembly may enable the pairs of signal vias to be positioned more adjacent to one another without reducing signal integrity.

In some aspects, the techniques described herein relate to an apparatus including: a layer of a printed circuit board; a first pair of signal vias extending through the layer and configured to propagate respective signals; a second pair of signal vias extending through the layer and configured to propagate respective signals; a first plurality of ground vias extending through the layer and at least partially circumferentially surrounding a first signal via of the first pair of signal vias; and a second plurality of ground vias extending through the layer and at least partially circumferentially surrounding a second signal via of the second pair of signal vias, wherein the first plurality of ground vias and the second plurality of ground vias share a common ground via.

In some aspects, the techniques described herein relate to an apparatus, wherein the first pair of signal vias, the second pair of signal vias, and the common ground via are offset from one another along a first axis and aligned with one another along a second axis that is perpendicular to the first axis.

In some aspects, the techniques described herein relate to an apparatus, including an additional ground via extending through the layer, wherein the additional ground via is aligned with the common ground via along the first axis and offset from the common ground via along the second axis.

In some aspects, the techniques described herein relate to an apparatus, wherein the first plurality of ground vias includes a first ground via and a second ground via, wherein the first ground via and the second ground via are aligned with one another along the first axis and offset from one another along the second axis.

In some aspects, the techniques described herein relate to an apparatus, wherein the first plurality of ground vias includes a first ground via, the second plurality of ground vias includes a second ground via, and the first ground via and the second ground via are offset from one another along the first axis and aligned with one another along the second axis.

In some aspects, the techniques described herein relate to an apparatus, including a third plurality of ground vias extending through the layer and at least partially surrounding a third signal via of the first pair of signal vias, wherein the first plurality of ground vias includes a first ground via, the third plurality of ground vias includes a second ground via, and the first ground via and the second ground via are offset from one another along the first axis and aligned with one another along the second axis.

In some aspects, the techniques described herein relate to an apparatus, including a trace coupled to the first signal via or the third signal via of the first pair of signal vias, wherein the trace is routed along the layer of the printed circuit board in a direction away from the first ground via or away from the second ground via.

In some aspects, the techniques described herein relate to an apparatus, including a plurality of ground microvias formed through the layer and surrounding the trace.

In some aspects, the techniques described herein relate to an apparatus, wherein the layer is a first outer layer extending along a first side of the printed circuit board, the printed circuit board includes a second outer layer extending along a second side, opposite the first side, of the printed circuit board, the apparatus includes a third pair of signal vias extending through the second outer layer and configured to propagate respective signals, and the third pair of signal vias extends in overlap with the first pair of signal vias and/or with the second pair of signal vias at an inner layer between the first outer layer and the second outer layer.

In some aspects, the techniques described herein relate to an apparatus, wherein the layer is a power layer that includes a ground portion, and the first plurality of ground vias and the second plurality of ground vias extend through the ground portion.

In some aspects, the techniques described herein relate to a method including: forming adjacent pairs of signal vias through a layer of a printed circuit board; forming a first plurality of ground vias through the layer of the printed circuit board to at least partially circumferentially surround a first signal via of a first pair of signal vias of the adjacent pairs of signal vias; and forming a second plurality of ground vias through the layer of the printed circuit board to at least partially circumferentially surround a second signal via of a second pair of signal vias of the adjacent pairs of signal vias, wherein the first plurality of ground vias and the second plurality of ground vias include a common ground via.

In some aspects, the techniques described herein relate to a method, wherein the layer includes a power shape with a cutout, and the adjacent pairs of signal vias, the first plurality of ground vias, and the second plurality of ground vias are formed through the cutout.

In some aspects, the techniques described herein relate to a method, further including positioning a ground shape within the cutout, wherein the adjacent pairs of signal vias, the first plurality of ground vias, and the second plurality of ground vias are formed through ground shape.

In some aspects, the techniques described herein relate to a method, further including coupling a trace to the first signal via or to the second signal via and routing the trace along the layer.

In some aspects, the techniques described herein relate to a method, wherein the layer is a first outer layer extending along a first side of the printed circuit board, the printed circuit board includes a second outer layer extending along a second side, opposite the first side, of the printed circuit board, and the method further includes forming an additional pair of signal vias extending through the second outer layer in overlap with the adjacent pair of signal vias at an inner layer between the first outer layer and the second outer layer.

In some aspects, the techniques described herein relate to an apparatus including: a first pair of signal vias of a printed circuit board, wherein the first pair of signal vias are configured to propagate respective signals; a second pair of signal vias of the printed circuit board, wherein the second pair of signal vias are configured to propagate respective signals, and the signal vias of the first pair of signal vias and the second pair of signal vias are offset from one another along a first axis and aligned with one another along a second axis that is perpendicular to the first axis; and a single ground via positioned between the first pair of signal vias and the second pair of signal vias along the first axis.

In some aspects, the techniques described herein relate to an apparatus, wherein the single ground via is positioned equidistant to a first signal via of the first pair of signal vias and a second signal via of the second pair of signal vias.

In some aspects, the techniques described herein relate to an apparatus, including: a first plurality of ground vias circumferentially surrounding the first signal via of the first pair of signal vias; and a second plurality of ground vias circumferentially surrounding the second signal via of the second pair of signal vias, wherein the single ground via is of both the first plurality of ground vias and the second plurality of ground vias.

In some aspects, the techniques described herein relate to an apparatus, wherein a first signal via of the first pair of signal vias is positioned equidistant to the single ground via and a second signal via of the first pair of signal vias.

In some aspects, the techniques described herein relate to an apparatus, wherein the first pair of signal vias, the second pair of signal vias, and the single ground via extend through a cutout of a power shape of the printed circuit board to avoid contact with the power shape.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

As used herein, the terms “approximately,” “generally,” “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to convey that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to convey that the given feature is within +/−5%, within +/−4%, within +/−3%, within +/−2%, within +/−1%, or even closer, to having the described nature, such as being parallel to another feature, being perpendicular to another feature, and so forth. Mathematical terms, such as “parallel” and “perpendicular,” should not be rigidly interpreted in a strict mathematical sense, but should instead be interpreted as one of ordinary skill in the art would interpret such terms. For example, one of ordinary skill in the art would understand that two lines that are substantially parallel to each other are parallel to a substantial degree, but may have minor deviation from exactly parallel.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. An apparatus comprising:
a layer of a printed circuit board;
a first pair of signal vias extending through the layer and configured to propagate respective signals;
a second pair of signal vias extending through the layer and configured to propagate respective signals;
a first plurality of ground vias extending through the layer and at least partially circumferentially surrounding a first signal via of the first pair of signal vias; and
a second plurality of ground vias extending through the layer and at least partially circumferentially surrounding a second signal via of the second pair of signal vias, wherein the first plurality of ground vias and the second plurality of ground vias share a common ground via.

2. The apparatus of claim 1, wherein the first pair of signal vias, the second pair of signal vias, and the common ground via are offset from one another along a first axis and aligned with one another along a second axis that is perpendicular to the first axis.

3. The apparatus of claim 2, further comprising an additional ground via extending through the layer, wherein the additional ground via is aligned with the common ground via along the first axis and offset from the common ground via along the second axis.

4. The apparatus of claim 2, wherein the first plurality of ground vias comprises a first ground via and a second ground via, wherein the first ground via and the second ground via are aligned with one another along the first axis and offset from one another along the second axis.

5. The apparatus of claim 2, wherein the first plurality of ground vias comprises a first ground via, the second plurality of ground vias comprises a second ground via, and the first ground via and the second ground via are offset from one another along the first axis and aligned with one another along the second axis.

6. The apparatus of claim 2, further comprising a third plurality of ground vias extending through the layer and at least partially surrounding a third signal via of the first pair of signal vias, wherein the first plurality of ground vias comprises a first ground via, the third plurality of ground vias comprises a second ground via, and the first ground via and the second ground via are offset from one another along the first axis and aligned with one another along the second axis.

7. The apparatus of claim 6, further comprising a trace coupled to the first signal via or the third signal via of the first pair of signal vias, wherein the trace is routed along the layer of the printed circuit board in a direction away from the first ground via or away from the second ground via.

8. The apparatus of claim 7, further comprising a plurality of ground microvias formed through the layer and surrounding the trace.

9. The apparatus of claim 1, wherein the layer is a first outer layer extending along a first side of the printed circuit board, the printed circuit board comprises a second outer layer extending along a second side, opposite the first side, of the printed circuit board, the apparatus comprises a third pair of signal vias extending through the second outer layer and configured to propagate respective signals, and the third pair of signal vias extends in overlap with the first pair of signal vias and/or with the second pair of signal vias at an inner layer between the first outer layer and the second outer layer.

10. The apparatus of claim 1, wherein the layer is a power layer that comprises a ground portion, and the first plurality of ground vias and the second plurality of ground vias extend through the ground portion.

11. A method comprising:
forming adjacent pairs of signal vias through a layer of a printed circuit board;
forming a first plurality of ground vias through the layer of the printed circuit board to at least partially circumferentially surround a first signal via of a first pair of signal vias of the adjacent pairs of signal vias; and
forming a second plurality of ground vias through the layer of the printed circuit board to at least partially circumferentially surround a second signal via of a second pair of signal vias of the adjacent pairs of signal vias, wherein the first plurality of ground vias and the second plurality of ground vias comprise a common ground via.

12. The method of claim 11, wherein the layer comprises a power shape with a cutout, and the adjacent pairs of signal vias, the first plurality of ground vias, and the second plurality of ground vias are formed through the cutout.

13. The method of claim 12, further comprising positioning a ground shape within the cutout, wherein the adjacent pairs of signal vias, the first plurality of ground vias, and the second plurality of ground vias are formed through ground shape.

14. The method of claim 11, further comprising coupling a trace to the first signal via or to the second signal via and routing the trace along the layer.

15. The method of claim 11, wherein the layer is a first outer layer extending along a first side of the printed circuit board, the printed circuit board comprises a second outer layer extending along a second side, opposite the first side, of the printed circuit board, and the method further comprises forming an additional pair of signal vias extending through the second outer layer in overlap with the adjacent pair of signal vias at an inner layer between the first outer layer and the second outer layer.

16. An apparatus comprising:
a first pair of signal vias of a printed circuit board, wherein the first pair of signal vias are configured to propagate respective signals;
a second pair of signal vias of the printed circuit board, wherein the second pair of signal vias are configured to propagate respective signals, and the signal vias of the first pair of signal vias and the second pair of signal vias are offset from one another along a first axis and aligned with one another along a second axis that is perpendicular to the first axis; and
a single ground via positioned between the first pair of signal vias and the second pair of signal vias along the first axis.

17. The apparatus of claim 16, wherein the single ground via is positioned equidistant to a first signal via of the first pair of signal vias and a second signal via of the second pair of signal vias.

18. The apparatus of claim 17, further comprising:
a first plurality of ground vias circumferentially surrounding the first signal via of the first pair of signal vias; and
a second plurality of ground vias circumferentially surrounding the second signal via of the second pair of signal vias,
wherein the single ground via is of both the first plurality of ground vias and the second plurality of ground vias.

19. The apparatus of claim 16, wherein a first signal via of the first pair of signal vias is positioned equidistant to the single ground via and a second signal via of the first pair of signal vias.

20. The apparatus of claim 16, wherein the first pair of signal vias, the second pair of signal vias, and the single ground via extend through a cutout of a power shape of the printed circuit board to avoid contact with the power shape.
